(19) United States
(12) Patent Application Publication
(10) Pub. No.: US 2014/0313443 A1
(43) Pub. Date: Oct. 23, 2014

(54) DISPLAY PANEL, TRANSISTOR, AND THE MANUFACTURING METHOD THEREOF

(71) Applicant: Shenzhen China Star Optoelectronics Technology Co. Ltd., Shenzhen, Guangdong (CN)

(72) Inventors: Cheng-Lung Chiang, Shenzhen City (CN); Po-Lin Chen, Shenzhen City (CN)

(73) Assignee: Shenzhen China Star Optoelectronics Technology Co., Ltd., Shenzhen, Guangdong (CN)

(21) Appl. No.: 13/884,307

(22) PCT Filed: Apr. 24, 2013
(86) PCT No.: PCT/CN2013/074588

§ 371 Date: May 9, 2013

(30) Foreign Application Priority Data
Apr. 22, 2013 (CN) 2013101405693

(51) Int. Cl. H01L 29/423; H01L 29/786; G02F 1/1368

(52) U.S. Cl. CPC H01L 29/42384; G02F 1/1368; H01L 29/78606; H01L 2029/42388
USPC 349/42; 438/104; 257/43

(57) ABSTRACT

A display panel, a transistor and the manufacturing method thereof are disclosed. The manufacturing method includes: forming a first electrode, a first insulation layer, a sacrificial layer, and a second/third electrode metal layer on a substrate in turn; etching the second/third electrode metal layer to expose at least portions of the sacrificial layer; and dry-etching the at least portions of the exposed sacrificial layer to expose at least portions of the first insulation layer. The etching selectivity ratio of the sacrificial layer to the first insulation layer is larger than a first value when the conditions of the etching process are the same. The first value is larger than one, in this way, the stability and the electron mobility of the transistor are enhanced.

### BACKGROUND OF THE INVENTION

1. Field of the Invention

Embodiments of the present disclosure relate to electronic technology, and more particularly to a display panel, a transistor and the manufacturing method thereof.

2. Discussion of the Related Art

Comparing to etching-stop thin film transistor (TFT) devices, coplanar TFT devices have a shorter channel length than the etching-stop TFT devices while fewer amounts of photo masks in the manufacturing process are needed. In addition, the manufacturing process is shorter and the power consumption is lower.

As shown in FIG. 1, the coplanar TFT devices include a gate 101, a gate insulation layer 102, a source/dram layer 103, a semiconductor layer 104, and a passivation layer 105. The source drain layer 103 includes a molybdenum metal layer 1031 and an alumni metal layer 1032. The molybdenum metal layer 1031 contacts the gate insulation layer 102 and is provided as a bottom of the source/drain layer 103 to enhance an adhesive force between the source/drain layer 101 and the gate insulation layer 102.

As shown in FIG. 2, the source/drain layer 103 is etched in the TFT devices manufacturing process. A photoresist layer is formed on the source/drain layer 103 before the etching process. In step S1, a dry etching process is applied to the alumni metal layer 1032 of the source/drain layer. In step S2, the dry etching process is applied to the molybdenum metal layer 1031. In step S3, an over etching process is applied to the molybdenum metal layer 1031. As an etching selectivity ratio of the molybdenum metal layer 1031 to the gate insulation layer 102 is not good, the gate insulation layer 102 may be damaged in the over etching process. As indicated, by the dash lines in step S3 (FIG. 2), the over etching process applied to the molybdenum metal layer 1031 may damage portions of the gate insulation layer 102 so that the stability and the electron mobility of the TFT devices are reduced.

### SUMMARY

The object of the claimed invention is to provide a display panel, a transistor, and the manufacturing method thereof to enhance the stability and the electron mobility of the TFT devices.

In one aspect, a transistor manufacturing method includes: a first forming step for forming a first electrode, a first insulation layer, a sacrificial layer, and a second/third electrode metal layer on a substrate in turn; dry-etching the second/third electrode metal layer to expose at least portions of the sacrificial layer and forming a corresponding second electrode and a corresponding third electrode of the transistor, wherein an etching selectivity ratio of the second/third electrode metal layer to the sacrificial layer is smaller than a second value when conditions of the etching process are the same, and the second value is smaller than one; dry-etching the at least portions of the exposed sacrificial layer to expose at least portions of the first insulation layer, the etching selectivity ratio of the sacrificial layer to the first insulation layer is larger than a first value when the conditions of the etching process are the same, and the first value is larger than one; a second forming step for forming a semiconductor layer on the at least portions of the exposed first insulation layer; and disposing a second insulation layer on the semiconductor layer to protect the semiconductor layer.

Wherein the second/third electrode metal layer includes a first metal layer and a second metal layer, the first metal layer includes at least molybdenum or titanium metal, and the second metal layer includes alumni metal; and the first forming step further includes: forming the first electrode, the first insulation layer and the sacrificial layer on the substrate in turn; and forming the first metal layer and the second metal layer on the sacrificial payer in turn to be cooperatively provided as the second/third electrode metal layer.

Wherein the transistor is a thin film transistor (TFT), the first electrode of the transistor corresponds to a gate of the TFT, the second electrode of the transistor corresponds to a source of the TFT, and the third electrode of the transistor corresponds to a drain of the TFT.

In another aspect, a transistor includes: a first electrode, a first insulation layer formed on the first electrode, a sacrificial layer formed on the first insulation layer, a second/third electrode metal layer formed on the sacrificial layer, and a semiconductor layer; an etching opening in the same location of the sacrificial layer and the second/third electrode metal layer such that the first insulation layer contacts the semiconductor layer; and wherein an etching process is applied to the sacrificial layer and the second/third electrode metal layer to form the etching opening, an etching selectivity ratio of the second/third electrode metal layer to the sacrificial layer is larger than a first value when the conditions of the etching process are the same, and the first value is larger than one.

Wherein the sacrificial layer is made by Silicon nitride (SiNx), and the first insulation layer is made by silicon oxide (SiOx).

Wherein the second/third electrode metal layer includes a first metal layer and a second metal layer above the first metal layer, the first metal layer is a molybdenum or a titanium metal layer, the second metal layer is arm alumni metal layer, and the first metal layer is above the sacrificial layer.

Wherein during the opening forming process, the etching selectivity ratio of the second/third, electrode metal layer to the sacrificial layer is less than a second value when the conditions of the etching process are the same and the second value is smaller than one.

Wherein the transistor further includes a second insulation layer disposed on the semiconductor layer to protect the semiconductor layer.

Wherein the semiconductor layer is a metal oxide layer including at least one of the zinc, tin, indium, or gallium oxide.

Wherein the transistor is a thin film transistor (TFT), the first electrode of the transistor corresponds to a gate of the TFT the second electrode of the transistor corresponds to a source of the TFT and the third electrode of the transistor corresponds to a drain of the TFT.

In another aspect, a display panel includes: an array substrate, a color filter substrate, and a liquid crystal layer between the array substrate and the color filter substrate; the array substrate includes at least one transistor, the transistor includes: a first electrode, a first insulation layer formed on the first electrode, a sacrificial layer formed on the first insulation layer, a second/third electrode metal layer formed on the sacrificial layer, and a semiconductor layer; an etching opening in the same location of the sacrificial layer and the second/third electrode metal layer such that the first insulation layer contacts the semiconductor layer; and wherein an etching process is applied to the sacrificial layer and the second/third electrode metal layer to form the etching opening, an etching selectivity ratio of the second/third electrode metal layer to the sacrificial layer is larger than a first value when the conditions of the etching process are the same, and the first value is larger than one.

Wherein the sacrificial layer is made by Silicon nitride (SiNx), and the first insulation layer is made by silicon oxide (SiOx).

Wherein the second/third electrode metal layer includes a first metal layer and a second metal layer on the first metal layer, the first metal layer is a molybdenum or a titanium metal layer, and the second metal layer is an alumni metal layer, and the first metal layer is above the sacrificial layer.

Wherein during the opening forming process, the etching selectivity ratio of the second/third electrode metal layer to the sacrificial layer is less than a second value when the conditions of etching process are the same, and the second value is smaller than one.

Wherein the transistor further includes a second insulation layer disposed on the semiconductor layer to protect the semiconductor layer.

Wherein the semiconductor layer is a metal oxide layer including at least one of the zinc tin, indium, or gallium oxide.

Wherein the transistor is a thin film transistor (TFT), the first electrode of the transistor corresponds to a gate of the TFT, the second electrode of the transistor corresponds to a source of the TFT, and the third electrode, of the transistor corresponds to a drain of the TFT.

The manufacturing method includes forming a first electrode, a first insulation layer, a sacrificial layer, and a second/third electrode metal layer on a substrate in turn. As the sacrificial layer is arranged between the first insulation layer and the second/third electrode metal layer, the first insulation is prevented from being damaged when the second/third electrode metal layer is etched. In addition, the sacrificial layer is etched to expose at least portions of the first insulation layer. The etching selectivity ratio of the sacrificial layer to the first insulation layer is larger than a first value, and the first value is larger than one. That is the etching speed of the sacrificial layer is larger than that of the first insulation layer. The gate insulation layer is prevented from being damaged when the sacrificial layer is etched. As such, the stability and the electron mobility of the transistor are enhanced.

### BRIEF DESCRIPTION OF THE DRAWINGS

FIG. 1 is a schematic view of a conventional TFT.

FIG. 2 are schematic views showing the etching process of the source and the drain of the TFT of FIG. 1 in the manufacturing process.

FIG. 3 is a flowchart of the manufacturing method of the transistor in accordance with one embodiment.

FIG. 4 are schematic views showing the manufacturing process of the transistor in accordance with one embodiment.

FIG. 5 is a schematic view of the transistor in accordance with one embodiment.

FIG. 6 is a schematic view of the display panel in accordance with one embodiment.

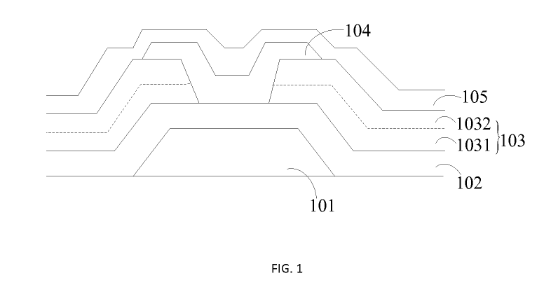

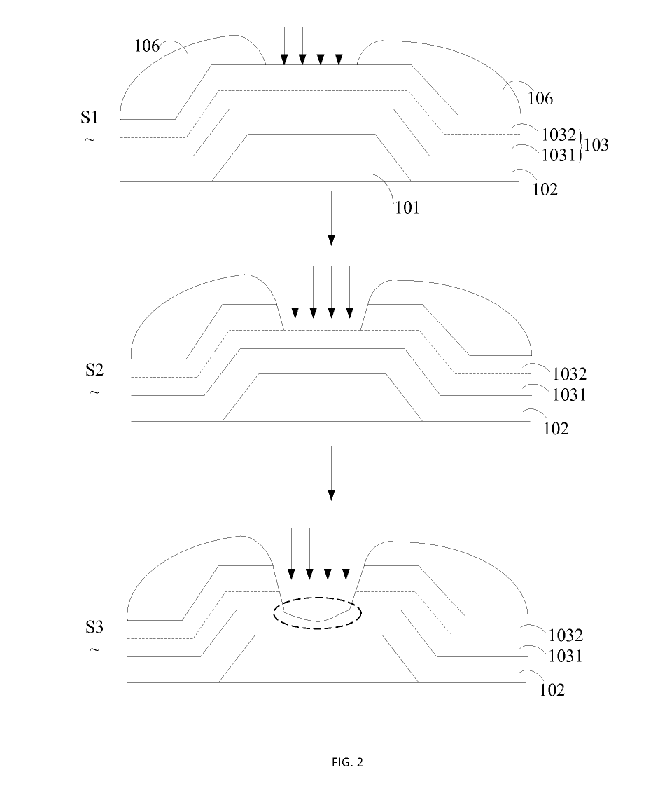

### DETAILED DESCRIPTION OF THE EMBODIMENTS

Embodiments of the invention will now be described more fully hereinafter with reference to the accompanying drawings, in which embodiments of the invention are shown.

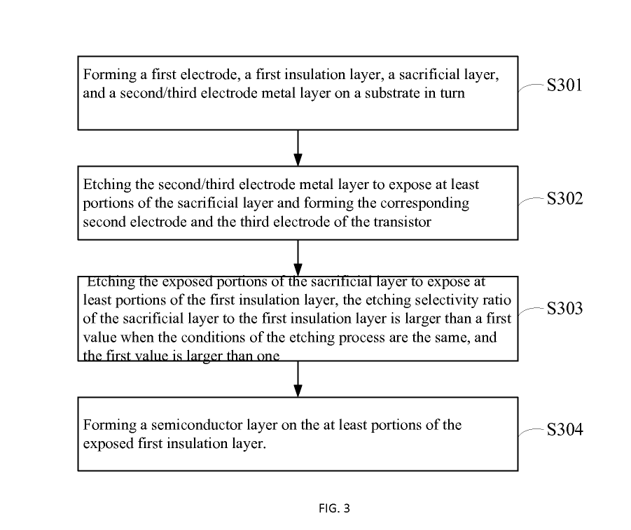

FIG. 3 is a flowchart of the manufacturing method of the transistor in accordance with one embodiment. In step S301, a first electrode 302, a first insulation layer 303, a sacrificial layer 304, and a second/third electrode metal layer 305 are formed on a substrate in turn.

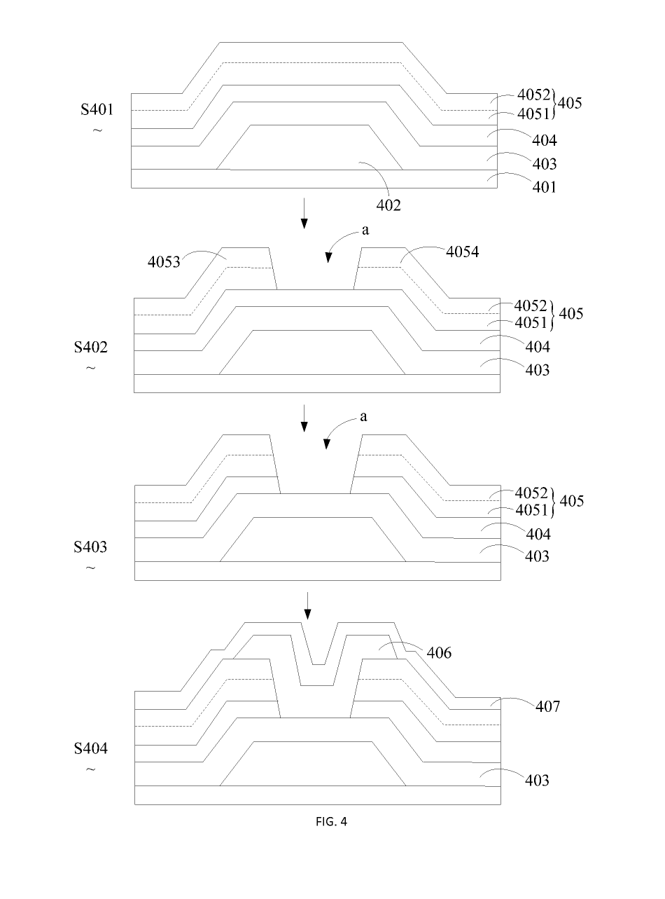

The manufacturing process of the transistor will be described with reference to the sub-steps in FIG. 4. In step S401, a substrate 401 is provided. The substrate 401 may be a glass substrate. Firstly, the substrate 401 is cleaned and then dried. A metallic film is then sputtered onto the substrate 401 to form the metal film provided as the first electrode 402. By exposing, etching, striping the metal film, the pattern of the electrode 402 is formed on the substrate 401. The first insulation layer 403 is then covered on the first electrode 402.

Afterward, the sacrificial layer 404 and the second/third electrode metal layer 405 are formed on the first insulation layer 403 in turn.

The first insulation layer 403 is made by silicon oxide (SiOx). The sacrificial layer 404 is made by silicon nitride (SiNx). The second/third electrode metal layer 405 has a stack structure including a first metal layer 4051 and a second metal layer 4052. In the embodiment, the first metal layer 4051 is a molybdenum metal layer, and the second metal layer 4052 is an alumni metal layer. After the sacrificial layer 404 is formed, the first metal layer 4051 and the second metal layer 4052 are formed on the sacrificial layer 404 in turn so as to be cooperatively provided as the second/third electrode metal layer 405. In addition, the first metal layer 4051 may be made by material including, but not limited to, titanium. Thus, the second/third electrode metal layer 405 has a stack structure including titanium/alumni. The first insulation layer 403 and the sacrificial layer 404 may be a hybrid layer including silicon oxide (SiOx) or the compound of silicon oxide.

In step S302, the second/third electrode metal layer 405 is etched so as to expose at least portions of the sacrificial layer 404. In this way, the second electrode 4053 and the third electrode 4054 of the transistor are formed.

The sub-step S402 in FIG. 4 also shows that the second/third electrode metal layer 405 forms the second electrode 4053 and the third electrode 4054.

In the embodiment, the transistor is a three-terminal element. The first electrode 402 is a control end of the transistor, while the second electrode 4053 and the third electrode 4054 are respectively an input end and an output end of the transistor. Specifically, the second metal layer 4052 is etched so that portions of the first metal layer 4051 are exposed. The exposed portions of the first metal layer 4051 is then etched to complete the etching of the second/third electrode metal layer 405 such that a corresponding etching opening (“a”) is formed. The second electrode 4053 and the third electrode 4054 are correspondingly formed. At the same time, portions of the sacrificial layer 404 are exposed. The second electrode 4053 and the third electrode 4054 are disconnected due to the etching opening (“a”).

The second/third electrode metal layer 405 is dry-etched. The patterns of the second electrode 4053 and the third electrode 4054 are formed by applying the ion bombardment toward the second/third electrode metal layer 405. As such the second electrode 4053 and the third electrode 4054 of the transistor are formed. The sacrificial layer 404 is between the second/third electrode metal layer 405 and the first insulation layer 403. During the over-etching process of the first metal layer 4051, the first insulation layer 403 is prevented from being damaged due to the sacrificial layer 404.

In step S303, the exposed portions of the sacrificial layer 404 are etched such that at least portions of the first insulation layer 403 are exposed. While the conditions of the etching process are the same, the etching selectivity ratio of the sacrificial layer 404 to the first insulation layer 403 is larger than a first value. In the embodiment, the first value is larger than one.

Corresponding to the sub-step S403 in FIG. 4, the exposed portions of the sacrificial layer 404 is etched so as to expose portions of the first insulation layer 403. In this way, the first insulation layer 403 may contact the semiconductor layer formed afterward. In addition, the etching opening (“a”) is formed in the same location of the sacrificial layer 404 and the second/third electrode metal layer 405. Similarly, the same dry etching process is applied to the exposed sacrificial layer 404. Under the same circumstance, the etching selectivity ratio of the sacrificial layer 404 and the first insulation layer 403 is larger than the first value. The etching selectivity ratio indicates the ratio of the etching speed of various materials. The etching selectivity ratio may be calculated by the equation:

The etching selectivity ratio=Etching speed of the material needed to be etched (“etched material”)/Etching speed of material not needed to be etched (“non-etched material”);

It is understood that the non-etched material may be damaged in the etching process. Thus, the higher etching selectivity ratio is expected. For example, during the etching process, the sacrificial layer 404 is the etched material, and the first insulation layer 403 is the non-etched material. As the etching selectivity ratio is larger than one, the etching speed of the sacrificial layer 404 is taster than that of the first insulation layer 403 so as to obtain a larger etching selectivity ratio. In the embodiment, the first value is 3.5. Under the circumstance, the first insulation layer 403 is prevented from being damaged while the sacrificial layer 404 is etched. In other embodiments, the first value may be 2.0, 3.0, 4.5 or other values larger than one.

In step S304, a semiconductor layer 406 is formed on the at least portions of the exposed first insulation layer 403.

Corresponding to the sub-step S404 in FIG. 4, the semiconductor layer 406 is formed within the etching opening (“a”) and contacts the first insulation layer 403. The semiconductor layer 406 is a metal oxide semiconductor layer. In the embodiment, the semiconductor layer 406 is a zinc oxide (ZnO) semiconductor layer. In other embodiments, the semiconductor layer 406 may be other metallic oxide, such as tin, indium, or gallium oxide. Also, the semiconductor layer 406 may be turned by two or a plurality of metal oxide. The second electrode 4053 and the third electrode 4054 of the transistor connect to the semiconductor layer 406. The second electrode 4053 and the third electrode 4054 are electrically connected when the first electrode 402 supplies voltage signals by the semiconductor layer 406. Alternatively, the second electrode 4053 and the third electrode 4054 are not electrically connected when the first electrode 402 does not supply the voltage signals.

After the semiconductor layer 406 is formed, a second insulation layer 407 is disposed on the semiconductor layer 406 so as to prevent the semiconductor layer 406 from being damaged. The second insulation layer 407 is the passivation layer.

It is to be noted that when the dry-etching process is applied to the second/third electrode metal layer 405, the etching selectivity ratio of the second/third electrode metal layer 405 to the sacrificial layer 404 is smaller than a second value. The second value is smaller than one. That is, the etching selectivity ratio of the second/third electrode metal layer 405 to the sacrificial layer 404 is smaller. In one embodiment, the second value is 0.8. It can be understood that the sacrificial layer 404 below the second/third electrode metal layer 405 may be damaged during the etching process when the etching selectivity ratio is smaller. However, as the sacrificial layer 404 has to be etched in the later process, the smaller etching selectivity ratio is acceptable. In other embodiments, the second value may be 0.3, 0.5, 0.6, or values smaller than one.

In one embodiment, the transistor may be the co-planar oxide thin film transistor (TFT). The first electrode 402 of the transistor corresponds to the gate of the TFT. The second electrode 4053 of the transistor corresponds to the source of the TFT. The third electrode 4054 of the transistor corresponds to the drain of the TFT. The transistor may be other three-terminal transistors such as triode or Darlington transistor.

In view of the above, the sacrificial layer 404 is formed to prevent the first insulation layer 403 from being damaged when the second/third electrode metal layer 405 is etched. In addition, a larger etching selectivity ratio is selected such that the first insulation layer 403 is prevented from being etched when the sacrificial layer 404 is etched. As such, the stability and the electron mobility of the transistor are enhanced.

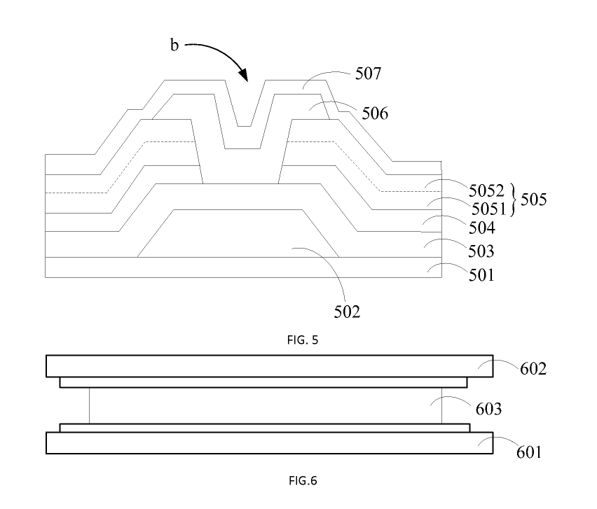

Referring to FIG. 5, the transistor includes the first electrode 502, the first insulation layer 503 formed on the first electrode 502, the sacrificial layer 504 formed on the insulation layer 503, the second/third electrode metal layer 505 formed on the sacrificial layer 504, and the semiconductor layer 506. Furthermore, the first insulation layer 503 and the sacrificial layer 504 are silicon nitride layers. The second/third electrode metal layer 505 includes a first metal layer 5051 and a second metal layer 5052 formed on the first metal layer 5051. The first metal layer 5051 is above the sacrificial layer 504. The first metal layer 5051 is a molybdenum or a titanium metal layer. The second metal layer 5052 is an alumni metal layer.

The etching opening (“b”) is formed in the same location of the sacrificial layer 504 and the second/third electrode metal layer 505 such that the insulation layer 503 contacts the semiconductor layer 506. The semiconductor layer 506 is the metal oxide semiconductor layer including zinc oxide (ZnO). In other embodiments, the semiconductor layer 506 may be other metal oxide layer including, but not limited to, indium metal oxide. In addition, the semiconductor layer 506 may by a hybrid metal oxide layer including a plurality of metal oxide, such as tin, or gallium oxide. The semiconductor layer 506 is formed within the etching opening (“b”). The second/third electrode metal layer 505 corresponds to the second electrode and the third electrode of the transistor. The second electrode and the third electrode are connected by the semiconductor layer 506. The second electrode and the third electrode are electrically connected via the semiconductor layer 506, and are electrically disconnected when the transistor is power off

The etching opening (“b”) is formed by dry-etching the sacrificial layer 504 and the second/third electrode metal layer 505. Specifically, during the opening forming process of the sacrificial layer 504, the etching selectivity ratio of the sacrificial layer 504 to the insulation layer 503 is larger than the first value, which is larger than one. In this way, the higher etching selectivity ratio is obtained such that the insulation layer 503 is prevented from being damaged when the sacrificial layer 504 is etched. In addition, during the opening (“b”) forming process of the second/third electrode metal layer 505, the etching selectivity ratio of the second/third electrode metal layer 505 to the sacrificial layer 504 is smaller than the second value. The second value is smaller than one, and thus the smaller etching selectivity ratio is obtained. The sacrificial layer 504 below the secondithird electrode metal layer 505 may be damaged during the etching process when the etching selectivity ratio is smaller. However, as the sacrificial layer 504 has to he etched in the later process, the smaller etching selectivity ratio is acceptable. In addition, the sacrificial layer 504 is between the second/thud electrode metal layer 505 and the first insulation layer 503. During the etching process of the second/third electrode metal layer 505, the first insulation layer 503 is prevented from being damaged due to the sacrificial layer 504.

Furthermore, the transistor includes a second insulation layer 507, which is the passivation layer for protecting the semiconductor layer 506 from being damaged.

In one embodiment, the transistor may be the TFT The first electrode 502 of the transistor corresponds to the gate of the TFT. The second electrode of the transistor corresponds to the source of the TFT. The third electrode of the transistor corresponds to the drain of the TFT The transistor may be other three-terminal transistor such as triode or Darlington transistor.

The etching opening is formed in the same location of the sacrificial layer 504 and the second/third electrode metal layer 505. During the opening forming process, the etching selectivity ratio of the sacrificial layer 504 and the first insulation layer 503 is larger than the first value. The first value is larger than one to prevent the insulation layer 503 from being damaged such that the stability and the electron mobility of the transistor are enhanced.

In one embodiment, the display panel includes an array substrate 601, a color filter substrate 601 and a liquid crystal layer 603 between the array substrate 601 and the color filter substrate 602. The array substrate 601 includes the above transistor.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A transistor manufacturing method, comprising:
a first forming step for forming a first electrode, a first insulation layer, a sacrificial layer, and a second/third electrode metal layer on a substrate in turn;
dry-etching the second/third electrode metal layer to expose at least portions of the sacrificial layer and forming a corresponding second electrode and a corresponding third electrode of the transistor, wherein an etching selectivity ratio of the second/third electrode metal layer to the sacrificial layer is smaller than a second value when conditions of the etching process are the same, and the second value is smaller than one;
dry-etching the at least portions of the exposed sacrificial layer to expose at least portions of the first insulation layer, the etching selectivity ratio of the sacrificial layer to the first insulation layer is larger than a first value when the conditions of the etching process are the same, and the first value is larger than one;
a second forming step for forming a semiconductor layer on the at least portions of the exposed first insulation layer; and
disposing a second insulation layer on the semiconductor layer to protect the semiconductor layer.

2. The manufacturing method as claimed in claim 1, wherein the second/third electrode metal layer comprises a first metal layer and a second metal layer, the first metal layer comprises at least molybdenum or titanium metal, and the second metal layer comprises alumni metal; and the first forming step further comprises:
forming the first electrode, the first insulation layer and the sacrificial layer on the substrate in turn; and
forming the first metal layer and the second metal layer on the sacrificial payer in turn to be cooperatively provided as the second/third electrode metal layer.

3. The manufacturing method as claimed in claim 1 wherein the transistor is a thin film transistor (TFT), the first electrode of the transistor corresponds to a gate of the TFT, the second electrode of the transistor corresponds to a source of the TFT, and the third electrode of the transistor corresponds to a drain of the TFT.

4. A transistor, comprising:
a first electrode, a first insulation layer formed on the first electrode, a sacrificial layer formed on the first insulation layer, a second/third electrode metal layer conned on the sacrificial layer, and a semiconductor layer;
an etching opening in the same location of the sacrificial layer and the second/third electrode metal layer such that the first insulation layer contacts the semiconductor layer; and
wherein an etching process is applied to the sacrificial layer and the second/third electrode metal layer to form the etching opening, an etching selectivity ratio of the second/third electrode metal layer to the sacrificial layer is larger than a first value when the conditions of etching process are the same, and the first value is larger than one.

5. The transistor as claimed in claim 4, wherein the sacrificial layer is made by Silicon nitride (SiNx), and the first insulation layer is made by silicon oxide (SiOx).

6. The transistor as claimed in claim 4, wherein the second/third electrode metal layer comprises a first metal layer and a second metal layer above the first metal layer, the first metal layer is a molybdenum or a titanium metal layer, the second metal layer is an alumni metal layer, and the first metal layer is above the sacrificial layer.

7. The transistor as claimed in claim 4, wherein during the opening forming process, the etching selectivity ratio of the second/third electrode metal layer to the sacrificial layer is less than a second value when the conditions of the etching process are the same, and the second value is smaller than one.

8. The transistor as claimed in claim 4, wherein the transistor further comprises a second insulation layer disposed on the semiconductor layer to protect the semiconductor layer.

9. The transistor as claimed in claim 4, wherein the semiconductor layer is a metal oxide hoer including at least one of the zinc, tin, indium, or gallium oxide.

10. The transistor as claimed in claim 4, wherein the transistor is a thin film transistor (TFT), the first electrode of the transistor corresponds to a gate of the TFT, the second electrode of the transistor corresponds to a source of the TFT, and the third electrode of the transistor corresponds to a drain of the TFT.

11. A display panel, comprising:
an array substrate, a color filter substrate, and a liquid crystal layer between the array substrate and the color filter substrate;
the array substrate comprises at least one transistor, the transistor comprises:
a first electrode, a first insulation layer formed on the first electrode, a sacrificial layer formed on the first insulation layer, a second/third electrode metal layer formed on the sacrificial layer, and a semiconductor layer;
an etching opening in the same location of the sacrificial layer and the second/third electrode metal layer such that the first insulation layer contacts the semiconductor layer; and
wherein an etching process is applied to the sacrificial layer and the second/third electrode metal layer to firm the etching opening, an etching selectivity ratio of the second/third electrode metal layer to the sacrificial layer is larger than a first value when the conditions of the etching process are the same, and the first value is larger than one.

12. The display panel as claimed in claim 11, wherein the sacrificial layer is made by Silicon nitride (SiNx), and the first insulation layer is made by silicon oxide (SiOx).

13. The display panel as claimed in claim 11, wherein the second/third electrode metal layer comprises a first metal layer and a second metal layer on the first metal layer, the first metal layer is a molybdenum or a titanium metal layer, and the second metal layer is an alumni metal layer, and the first metal layer is above the sacrificial layer.

14. The display panel as claimed in claim 11, wherein during the opening forming process, the etching selectivity ratio of the second/third electrode metal layer to the sacrificial layer is less than a second value when the conditions of the etching process are the same, and the second value is smaller than one.

15. The display panel as claimed in claim 11, wherein the transistor further comprises a second insulation layer disposed on the semiconductor layer to protect the semiconductor layer.

16. The display panel as claimed in claim 11, wherein the semiconductor layer is a metal oxide layer including at least one of the zinc, tin, indium, or gallium oxide.

17. The display panel as claimed in claim 11, wherein the transistor is a thin film transistor (TFT), the first electrode of the transistor corresponds to a gate of the TFT, the second electrode of the transistor corresponds to a source of the TFT, and the third electrode or the transistor corresponds to a drain of the TFT.
